(19) United States
(12) Patent Application Publication
(10) Pub. No.: US 2026/0262288 A1
(43) Pub. Date: Sep. 3, 2026

(54) DISPLAY SUBSTRATE AND MANUFACTURING METHOD THEREOF

(71) Applicants: Beijing BOE Technology Development Co., Ltd., Beijing (CN); BOE Technology Group Co., Ltd., Beijing (CN)

(72) Inventors: Lizhong WANG, Beijing (CN); Guangcai YUAN, Beijing (CN); Ce NING, Beijing (CN); Tianmin ZHOU, Beijing (CN); Hui GUO, Beijing (CN)

(21) Appl. No.: 18/995,659

(22) PCT Filed: Apr. 17, 2024
(86) PCT No.: PCT/CN2024/088293

§ 371 Date: Jan. 16, 2025

(30) Foreign Application Priority Data
May 31, 2023 (CN) 202310639453.8

(51) Int. Cl. H10D 86/40; H10D 86/01; H10D 86/60

(52) U.S. Cl. CPC H10D 86/423; H10D 86/021; H10D 86/441; H10D 86/60

(57) ABSTRACT

A display substrate includes a base substrate, and a plurality of gate lines, a plurality of data lines, and a plurality of pixels on the base substrate. Each pixel includes a first thin film transistor, first and second display electrodes. The first thin film transistor has a gate connected to a gate line, a source connected to a data line through a first connection via, and a drain connected to the first display electrode through a second connection via. The display substrate further includes a first light-shielding layer on a side of the first thin film transistor close to the base substrate. The first light-shielding layer is made of a silicon-containing semiconductor material. An orthographic projection of the first light-shielding layer on the base substrate covers at least an orthographic projection of one of the first connection via or the second connection via on the base substrate.

### TECHNICAL FIELD

The present disclosure relates to the field of display technology, and specifically relates to a display substrate and a manufacturing method thereof.

### BACKGROUND

To electrically connect conductive structures of different layers in a display substrate, connection vias are required. The connection via is formed through a patterning process, and a size of the connection via will affect the resolution, bezel size, transmittance and the like of a product.

### SUMMARY

To solve at least one of the technical problems in the existing art, the present disclosure provides a display substrate and a manufacturing method thereof.

In a first aspect, an embodiment of the present disclosure provides a display substrate, including a base substrate, and a plurality of gate lines, a plurality of data lines, and a plurality of pixels on the base substrate; wherein each pixel includes a first thin film transistor, a first display electrode, and a second display electrode. wherein the first thin film transistor has a gate connected to a gate line, a source connected to a data line through a first connection via, and a drain connected to the first display electrode through a second connection via; and wherein
the display substrate further includes a first light-shielding layer on a side of the first thin film transistor close to the base substrate; the first light-shielding layer is made of a silicon-containing semiconductor material; and an orthographic projection of the first light-shielding layer on the base substrate covers at least an orthographic projection of one of the first connection via or the second connection via on the base substrate.

The first light-shielding layer includes a first light-shielding part and/or a second light-shielding part;
where the first light-shielding layer includes the first light-shielding part, an orthographic projection of the first light-shielding part on the base substrate covers the orthographic projection of the first connection via on the base substrate; and
where the first light-shielding layer includes the second light-shielding part, an orthographic projection of the second light-shielding part on the base substrate covers the orthographic projection of the second connection via on the base substrate.

An active layer of the first thin film transistor is made of a metal oxide, and is closer to the base substrate than the gate; and the first light-shielding layer further includes a third light-shielding part, and an orthographic projection of the third light-shielding part on the base substrate covers an orthographic projection of a channel region in the active layer on the base substrate.

For the third light-shielding part and the channel region having overlapped orthographic projections on the base substrate, a minimum distance between contours of the orthographic projections of the third light-shielding part and the channel region on the base substrate is between 0.5 μm and 5 μm.

The first light-shielding layer further includes a plurality of fourth light-shielding parts and/or a plurality of fifth light-shielding parts;
where the first light-shielding layer includes the fourth light-shielding parts, an orthographic projection of one fourth light-shielding part on the base substrate covers an orthographic projection of one gate line on the base substrate; and
where the first light-shielding layer includes the fifth light-shielding parts, an orthographic projection of one fifth light-shielding part on the base substrate covers an orthographic projection of one data line on the base substrate.

For the fourth light-shielding part and the gate line having overlapped orthographic projections on the base substrate, a minimum distance between contours of the orthographic projections of the fourth light-shielding part and the gate line on the base substrate is between 0.5 μm and 5 μm.

For the fifth light-shielding part and the data line having overlapped orthographic projections on the base substrate, a minimum distance between contours of the orthographic projections of the fifth light-shielding part and the data line on the base substrate is between 0.5 μm and 5 μm.

The display substrate includes a display region and a peripheral region around the display region, and the peripheral region includes a gate driver circuit on the base substrate; each shift register of the gate driver circuit includes a second thin film transistor; and an active layer of the second thin film transistor is disposed in the same layer as the first light-shielding layer.

The display substrate includes a display region and a peripheral region around the display region, and the peripheral region includes a gate driver circuit and a second light-shielding layer on the base substrate; an orthographic projection of the second light-shielding layer on the base substrate covers an orthographic projection of a channel region in an active layer of the first thin film transistor on the base substrate;

each shift register of the gate driver circuit includes a second thin film transistor; and a gate of the second thin film transistor is disposed in the same layer as the second light-shielding layer. The second connection via includes a first sub-via and a second sub-via sequentially arranged in a direction away from the base substrate; and the drain of the first thin film transistor is connected to a transfer electrode through the first sub-via, and the transfer electrode is connected to the first display electrode through the second sub-via.

An active layer of the first thin film transistor includes a first semiconductor section and a second semiconductor section; the first semiconductor section and the second semiconductor section each have a first end and a second end; the second end of the first semiconductor section is connected to the first end of the second semiconductor section; the first end of the first semiconductor section serves as the source of the first thin film transistor, and the second end of the second semiconductor section serves as the drain of the first thin film transistor; and
an extending direction of the second semiconductor section is intersected with an extending direction of the gate line, and along an extending direction of the data line, the first end and the second end of the second semiconductor section are located at two sides of the gate line, respectively.

Where the first light-shielding layer includes the first light-shielding part, for the first light-shielding part and the first connection via having overlapped orthographic projections on the base substrate, a minimum distance between contours of the orthographic projections of the first light-shielding part and the first connection via on the base substrate is between 0.5 μm and 5 μm.

Where the first light-shielding layer includes the second light-shielding part, for the second light-shielding part and the second connection via having overlapped orthographic projections on the base substrate, a minimum distance between contours of the orthographic projections of the second light-shielding part and the second connection via on the base substrate is between 0.5 μm and 5 μm.

Where the first light-shielding layer includes the first light-shielding part, an orthographic projection of the first light-shielding part on the base substrate has a contour in the shape of any one or more of a square, a rectangle, a parallelogram, a circle, an ellipse, an ellipse-like shape or an irregular shape.

Where the first light-shielding layer includes the second light-shielding part, an orthographic projection of the second light-shielding part on the base substrate has a contour in the shape of any one or more of a square, a rectangle, a parallelogram, a circle, an ellipse, an ellipse-like shape or an irregular shape.

An interlayer insulation layer is provided between the first display electrode and the second display electrode, and a third light-shielding layer is provided on a side of the second display electrode close to the interlayer insulation layer; and an orthographic projection of the third light-shielding layer on the base substrate covers an orthographic projection of the data line on the base substrate.

Where an active layer of the first thin film transistor is made of a metal oxide semiconductor material, the first light-shielding layer is made of a material including polysilicon; and where the active layer of the first thin film transistor is made of a polysilicon material, the first light-shielding layer is made of a material including amorphous silicon.

In a second aspect, an embodiment of the present disclosure provides a method for manufacturing a display substrate, including: providing a base substrate, and forming a plurality of gate lines, a plurality of data lines and a plurality of pixels on the base substrate; wherein each pixel is formed by forming a first thin film transistor, a first display electrode, and a second display electrode on the base substrate; wherein the first thin film transistor has a gate connected to a gate line, a source connected to a data line through a first connection via, and a drain connected to the first display electrode through a second connection via; and wherein the method further includes:
forming a first light-shielding layer on a side of the first thin film transistor close to the base substrate; wherein the first light-shielding layer is made of a silicon-containing semiconductor material; and
an orthographic projection of the first light-shielding layer on the base substrate covers at least an orthographic projection of one of the first connection via or the second connection via on the base substrate.

The first light-shielding layer includes a first light-shielding part and/or a second light-shielding part;
where the first light-shielding layer includes the first light-shielding part, an orthographic projection of the first light-shielding part on the base substrate covers the orthographic projection of the first connection via on the base substrate; and
where the first light-shielding layer includes the second light-shielding part, an orthographic projection of the second light-shielding part on the base substrate covers the orthographic projection of the second connection via on the base substrate.

An active layer of the first thin film transistor is made of a metal oxide, and is closer to the base substrate than the gate; and the first light-shielding layer further includes a third light-shielding part, and an orthographic projection of the third light-shielding part on the base substrate covers an orthographic projection of a channel region in the active layer on the base substrate.

The first light-shielding layer further includes a plurality of fourth light-shielding parts and/or a plurality of fifth light-shielding parts;
where the first light-shielding layer includes the fourth light-shielding parts, an orthographic projection of one fourth light-shielding part on the base substrate covers an orthographic projection of one gate line on the base substrate; and
where the first light-shielding layer includes the fifth light-shielding parts, an orthographic projection of one fifth light-shielding part on the base substrate covers an orthographic projection of one data line on the base substrate.

The method further includes forming a gate driver circuit on the base substrate; wherein each shift register of the gate driver circuit includes a second thin film transistor; and an active layer of the second thin film transistor is disposed in the same layer as the first light-shielding layer.

### BRIEF DESCRIPTION OF DRAWINGS

FIG. 1 shows a cross-sectional view of an exemplary display substrate.

FIG. 2 is a cross-sectional view of a display substrate according to an embodiment of the present disclosure.

FIG. 3 is a top view of a display substrate according to an embodiment of the

FIG. 4 is a schematic diagram showing a positional relationship between a first light-shielding part and a first connection via according to an embodiment of the present disclosure.

FIG. 5 is a schematic diagram showing a positional relationship between a second light-shielding part and a second connection via according to an embodiment of the present disclosure.

FIG. 6 is a schematic diagram of first/second light-shielding parts corresponding to connection vias according to an embodiment of the present disclosure.

FIG. 7 is a top view of another display substrate according to an embodiment of the present disclosure.

FIG. 8 is a cross-sectional view of a display substrate in a first example according to an embodiment of the present disclosure.

FIG. 9 is a top view of the display substrate in the first example according to an embodiment of the present disclosure.

FIG. 10 is a cross-sectional view of a display substrate in a second example according to an embodiment of the present disclosure.

FIG. 11 is a top view of the display substrate in the second example according to an embodiment of the present disclosure.

FIG. 12 is a cross-sectional view of a display substrate in a third example according to an embodiment of the present disclosure.

FIG. 13 is a top view of the display substrate in the third example according to an embodiment of the present disclosure.

FIG. 14 is a top view of a display substrate in a fourth example according to an embodiment of the present disclosure.

FIG. 15 is a top view of a display substrate in a fifth example according to an embodiment of the present disclosure.

FIG. 16 is a top view of a display substrate in a sixth example according to an embodiment of the present disclosure.

FIG. 17 is a flowchart and corresponding cross-sectional views of a method for manufacturing a display substrate according to an embodiment of the present disclosure.

### DETAIL DESCRIPTION OF EMBODIMENTS

To improve understanding of the technical solution of the present disclosure for those skilled in the art, the present disclosure will be described in detail with reference to accompanying drawings and specific implementations.

Unless otherwise defined, technical or scientific terms used in the present disclosure are intended to have general meanings as understood by those skilled in the art to which the present disclosure belongs. The words “first”, “second” and similar terms used in the present disclosure do not denote any order, quantity, or importance, but are used merely for distinguishing different components from each other. Likewise, the words “a”, “an”, or “the” and similar referents do not denote a limitation of quantity, but rather denote the presence of at least one. The word “comprise” or “include” or the like means that the element or item preceding the word contains elements or items that appear after the word or equivalents thereof, but does not exclude other elements or items. The terms “connected” or “coupled” and the like are not restricted to physical or mechanical connection, but may include electrical connection, either direct or indirect. The words “upper”, “lower”, “left”, “right”, and the like are merely used to indicate a relative positional relationship, and when an absolute position of the described object is changed, the relative positional relationship may be changed accordingly.

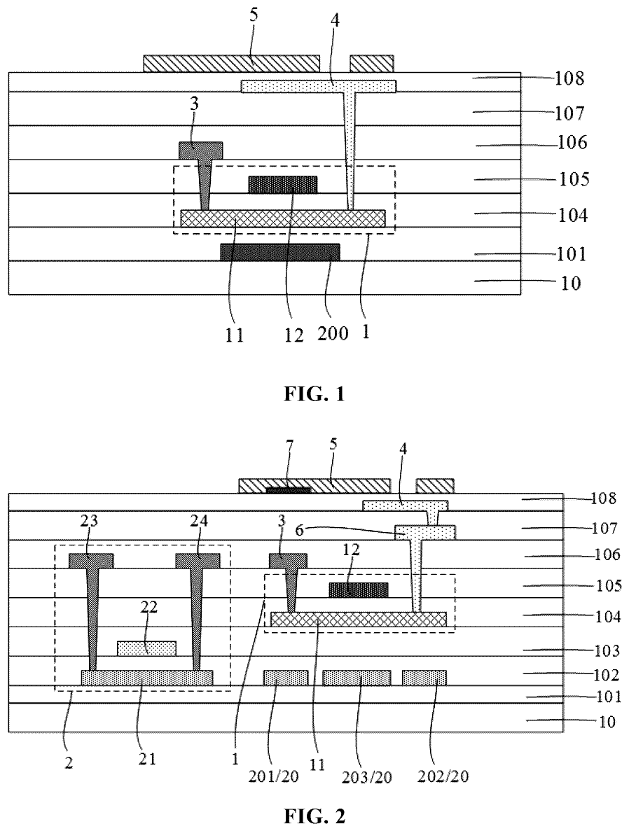

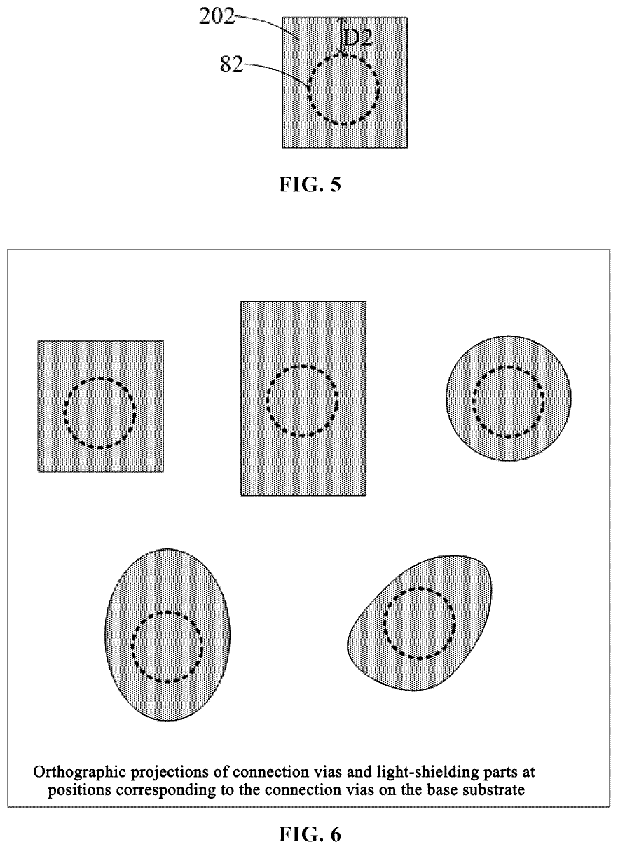

Before describing the display substrate and the manufacturing method thereof, and the display apparatus according to the embodiments of the present disclosure, it should be noted that in the embodiments of the present disclosure, the display substrate is mainly applied to a display apparatus with a high resolution (high PPI), such as a notebook computer (NB) or VR/AR display apparatus with a high refresh rate and a high PPI. Gate lines in the display substrate extend in a first direction and are arranged side by side in a second direction, while data lines extend in the second direction and are arranged side by side in the first direction. Pixels in the display substrate are arranged in an array, that is, form a plurality of columns arranged side by side in the first direction and a plurality of rows arranged side by side in the second direction. In the embodiments of the present disclosure, one of the first display electrode or the second display electrode mentioned is a pixel electrode, while the other is a common electrode. In the following examples, only the case where the first display electrode is a pixel electrode, and the second display electrode is a common electrode is taken as an example for illustration. Referring to FIGS. 1 and 3, FIG. 1 shows a cross-sectional view of an exemplary display substrate. The display substrate includes a plurality of gate lines 9, a plurality of data lines 3, and a plurality of pixels. Each pixel includes a first thin film transistor 1, a pixel electrode 4, and a common electrode 5 on the base substrate. In FIG. 1, the case where the first thin film transistor 1 is a top gate oxide thin film transistor (in which an active layer is made of a metal oxide semiconductor material) is taken as an example for illustration. A light-shielding layer, a first interlayer insulation layer 103, an active layer 11 of a first thin film transistor 1, a first gate insulation layer 104, a second interlayer insulation layer 105, a data line 3, a first passivation layer 106, a planarization layer 107, a pixel electrode 4, a second passivation layer 108, and a common electrode 5 are sequentially disposed on a base substrate 10. An orthographic projection of the light-shielding layer on the base substrate 10 covers an orthographic projection of a channel region in the active layer of the thin film transistor on the base substrate 10, so that the influence of light illumination on on/off properties of the first thin film transistor 1 can be prevented. A source contact region and a drain contact region in the active layer are used as a source and a drain of the thin film transistor, respectively, and it should be noted that to ensure conductivity of the source contact region and the drain contact region, the source contact region and the drain contact region in the active layer may be subjected to a conductorization process, such as ion doping and ion implantation. The data line 3 is connected to the source contact region (i.e., source) in the active layer through a first connection via 81 running through the second interlayer insulation layer 105 and the first gate insulation layer 104. The pixel electrode 4 is connected to the drain contact region (i.e., drain) in the active layer through a second connection via 82 running through the first gate insulation layer 104, the second interlayer insulation layer 105, the first passivation layer 106, and the planarization layer 107.

With the rise of the “meta universe” concept, there are increased market demands for ultra-high PPI displays. However, the aperture ratio and the contrast have become a bottleneck for improving the PPI, because a higher PPI means more pixels in a unit area, which requires signal lines (gate lines 9, data lines 3, and the like) of a larger footprint and results in a lower aperture ratio, and meanwhile, more connection vias (first connection vias 81 and second connection vias 82) are used and take a greater occupation, leading to more serious light leakage and thus a lower contrast of the display apparatus.

In view of the above technical problems, embodiments of the present disclosure provide the following technical solutions.

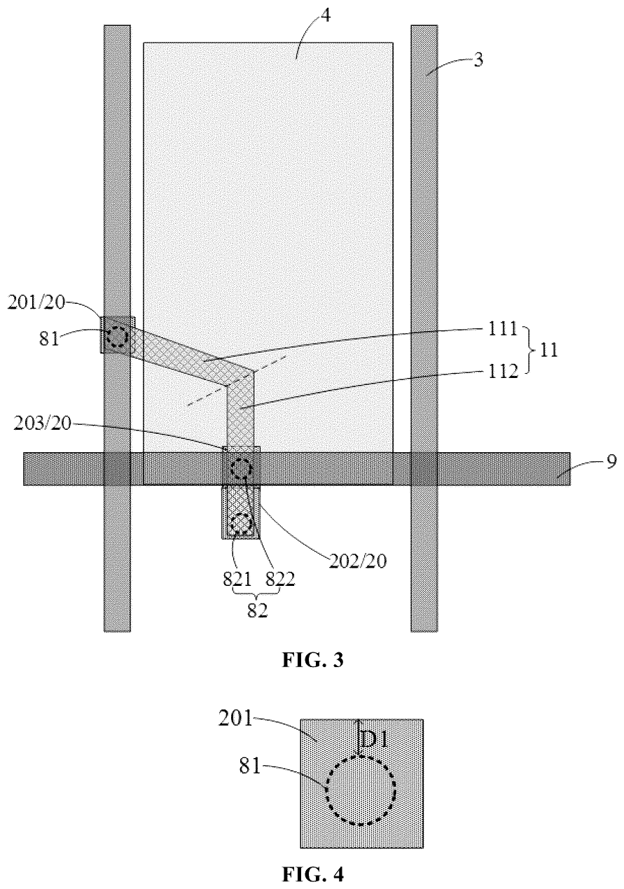

In a first aspect, FIG. 2 is a cross-sectional view of a display substrate according to an embodiment of the present disclosure; and FIG. 3 is a top view of a display substrate according to an embodiment of the present disclosure. As shown in FIGS. 2 and 3, an embodiment of the present disclosure provides a display substrate which may be applied to a VR display apparatus with a high PPI. The display substrate may include a base substrate 10, and a plurality of gate lines 9, a plurality of data lines 3, and a plurality of pixels on the base substrate 10. Each pixel includes a first thin film transistor 1, a pixel electrode 4, and a common display electrode. For each pixel, the first thin film transistor 1 has a gate 12 connected to a gate line 9, a source connected to a data line 3 through a first connection via 81, and a drain connected to the first pixel electrode 4 through a second connection via 82. In particular, In the embodiment of the present disclosure, a first light-shielding layer 20 is provided on a side of the first thin film transistor 1 close to the base substrate 10. An orthographic projection of the first light-shielding layer 20 on the base substrate 10 covers at least an orthographic projection of one of the first connection via 81 or the second connection via 82 on the base substrate 10. For example: the first light-shielding layer 20 includes a first light-shielding part 201 and/or a second light-shielding part 202. Where the first light-shielding layer 20 includes the first light-shielding part 201, an orthographic projection of the first light-shielding part 201 on the base substrate 10 covers the orthographic projection of the first connection via 81 on the base substrate 10. Where the first light-shielding layer 20 includes the second light-shielding part 202, an orthographic projection of the second light-shielding part 202 on the base substrate 10 covers the orthographic projection of the second connection via 82 on the base substrate 10. The first light-shielding layer 20 is made of a silicon-containing semiconductor material. For example: the first light-shielding layer 20 is made of polysilicon (poly-Si), amorphous silicon (a-Si) , or the like.

In the embodiment of the present disclosure, a silicon-containing semiconductor material is selected to form the first light-shielding layer 20 to shield the first connection via 81 and/or the second connection via 82, so that by means of the optical characteristics of the silicon-containing semiconductor material, ultraviolet light within a certain wavelength range can be selectively filtered while allowing transmission of visible light, and therefore, light leakage at positions of the connection vias can be reduced without affecting the aperture ratio.

In some examples, FIG. 4 is a schematic diagram showing a positional relationship between a first light-shielding part 201 and a first connection via 81 according to an embodiment of the present disclosure. As shown in FIG. 4, where the first light-shielding layer 20 includes the first light-shielding part 201, for the first light-shielding part 201 and the first connection via 81 having overlapped orthographic projections on the base substrate 10, a minimum distance DI between contours of the orthographic projections of the first light-shielding part 201 and the first connection via 81 on the base substrate 10 is about in a range of 0.5 μm to 5 μm. For example: the orthographic projection of the first light-shielding part 201 has a rectangular shape, and the minimum distance between contours of the orthographic projections of the first light-shielding part 201 and the first connection via 81 on the base substrate 10 refers to a minimum distance between an orthographic projection of any side of the first light-shielding part on the base substrate 10 and a contour of the orthographic projection of the first connection via on the base substrate 10. For specific dimensions of the first light-shielding part 201, specific parameters may be provided according to the specific product requirements.

In some examples, FIG. 5 is a schematic diagram showing a positional relationship between a second light-shielding part 202 and a second connection via 82 according to an embodiment of the present disclosure. As shown in FIG. 5, where the first light-shielding layer 20 includes the second light-shielding part 202, for the second light-shielding part 202 and the second connection via 82 having overlapped orthographic projections on the base substrate 10, a minimum distance D2 between contours of the orthographic projections of the second light-shielding part 202 and the second connection via 82 on the base substrate 10 is about in a range of 0.5 μm to 5 μm. For example: the orthographic projection of the second light-shielding part 202 has a rectangular shape, and the minimum distance between contours of the orthographic projections of the second light-shielding part 202 and the second connection via 82 on the base substrate 10 refers to a minimum distance between an orthographic projection of any side of the second light-shielding part on the base substrate 10 and a contour of the orthographic projection of the second connection via on the base substrate 10. For specific dimensions of the second light-shielding part 202, specific parameters may be provided according to the specific product requirements.

In some examples, FIG. 6 is a schematic diagram of light-shielding parts corresponding to connection vias according to an embodiment of the present disclosure. As shown in FIG. 6, the connection via may be the first connection via 81 or the second connection via 82 described above. Accordingly, where the connection via is the first connection via 81, the light-shielding part is the first light-shielding part 201; and where the connection via is the second connection via 82, the light-shielding part is the second light-shielding part 202. Specifically, where the first light-shielding layer 20 includes the first light-shielding part 201, an orthographic projection of the first light-shielding part 201 on the base substrate 10 has a contour in the shape of any one or more of a square, a parallelogram, a rectangle, a circle, an ellipse, an ellipse-like shape or other irregular shapes. The light leakage at the position of the first connection via 81 can be improved regardless of the shape of the first light-shielding part 201. Likewise, where the first light-shielding layer 20 includes the second light-shielding part 202, an orthographic projection of the second light-shielding part 202 on the base substrate 10 has a contour in the shape of any one or more of a square, a parallelogram, a rectangle, a circle, an ellipse, or an ellipse-like shape. The light leakage at the position of the first connection via 81 can be improved regardless of the shape of the second light-shielding part 202.

In some examples, the first thin film transistor 1 in the embodiments of the present disclosure may be an oxide thin film transistor, that is, the active layer 11 of the first thin film transistor 1 is made of an oxide semiconductor material. For example: the active layer 11 of the first thin film transistor 1 is made of IGZO, IGO, IGZTO, IZO, or In-OS (Lanthanide doped metal oxides).

Further, where the active layer 11 of the first thin film transistor 1 is made of an oxide semiconductor material and closer to the base substrate 10 than the gate, the first thin film transistor 1 is a top gate thin film transistor. With continued reference to FIG. 3, in addition to the first light-shielding part 201 and/or the second light-shielding part 202, the light-shielding layer 20 may further include a third light-shielding part 203, and an orthographic projection of the third light-shielding part 203 on the base substrate 10 covers an orthographic projection of a channel region in the active layer on the base substrate 10. By providing the third light-shielding part 203 that shields the channel region, the stability of the channel region can be improved. Moreover, since the third light-shielding part 203 is located in the first light-shielding layer 20, no additional process step is involved, and the film thickness of the display substrate will not be increased.

Further, for the third light-shielding part 203 and the channel region having overlapped orthographic projections on the base substrate 10, a minimum distance between contours of the orthographic projections of the third light-shielding part 203 the channel region on the base substrate 10 is about in a range of 0.5 μm to 5 μm. For specific dimensions of the third light-shielding part 203, specific parameters may be provided according to the specific product requirements.

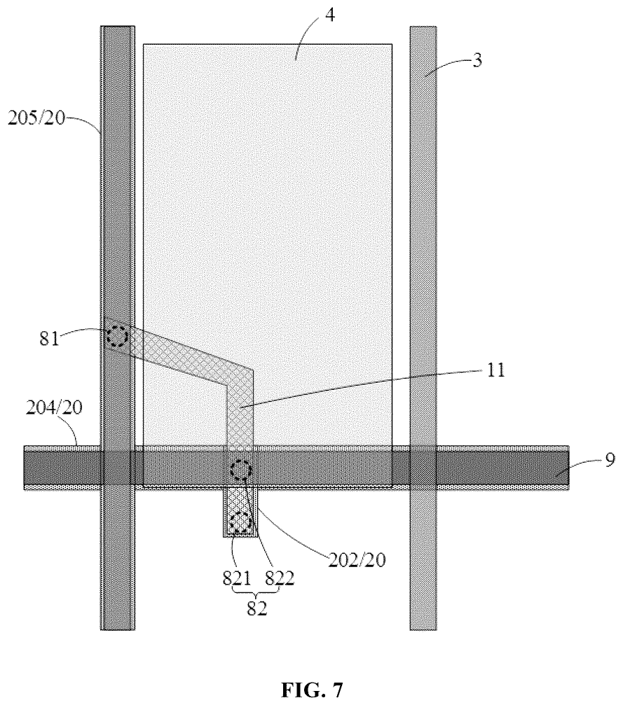

In some examples, FIG. 7 is a top view of another display substrate according to an embodiment of the present disclosure. As shown in FIG. 7, in addition to the first light-shielding part 201 and the second light-shielding part 202, the light-shielding layer 20 may further include a fourth light-shielding part 204, and an orthographic projection of the fourth light-shielding part 204 on the base substrate 10 covers an orthographic projection of the gate line 9 on the base substrate 10. The gate 12 of the first thin film transistor 1 is integrally formed with the gate line 9, or to put it another way, the gate line 9 includes the gate 12 of the first thin film transistor 1. In this case, the orthographic projection of the gate line 9 on the base substrate 10 covers an orthographic projection of the channel region in the active layer 11 of the first thin film transistor 1 on the base substrate 10. The fourth light-shielding part 204 can shield not only the gate line 9 but also the channel region in the active layer 11 of the first thin film transistor 1, so that the stability of the first thin film transistor 1 can be further improved. With continued reference to FIG. 7, the first light-shielding layer 20 may further include a fifth light-shielding part 205, and an orthographic projection of the fifth light-shielding part 205 on the base substrate 10 covers an orthographic projection of the data line 3 on the base substrate 10. The fifth light-shielding part 205 may be integrally formed with the first light-shielding part 201, or to put it another way, the fifth light-shielding part 205 includes the first light-shielding part 201, that is, the fifth light-shielding part 205 may further shield the first connection via 81. In the embodiment of the present disclosure, the fourth light-shielding part 204 and the fifth light-shielding part 205 are provided to shield the gate line 9 and the data line 3, respectively, because the gate line 9 and the data line 3 are not linear structures and are made of a metal material, which may cause light deflection and thus light leakage when light passes through edges of the metal signal lines, and in this case, light leakage can be effectively reduced by shielding the gate line 9 and the data line 3 by the fourth light-shielding part 204 and the fifth light-shielding part 205, respectively.

Further, for the fourth light-shielding part 204 and the gate line 9 having overlapped orthographic projections on the base substrate 10, a minimum distance between contours of the orthographic projections of the fourth light-shielding part 204 and the gate line 9 on the base substrate 10 is about in a range of 0.5 μm to 5 μm. For the fifth light-shielding part 205 and the data line 3 having overlapped orthographic projections on the base substrate 10, a distance between contours of the orthographic projections of the fifth light-shielding part 205 and the data line 3 on the base substrate 10 is about in a range of 0.5 μm to 5 μm. For specific dimensions of the fourth light-shielding part 204 and the fifth light-shielding part 205, specific parameters may be provided according to the specific product requirements.

In some examples, with continued reference to FIG. 2, the display substrate is divided into a display region and a peripheral region, the pixels are located in the display region, and both the gate lines 9 and the data lines 3 extend from the display region to the peripheral region. The display substrate further includes a gate driver circuit disposed on the base substrate 10 and located in the peripheral region. The gate driver circuit includes a plurality of cascaded shift registers, each of which has an output end electrically connected to one gate line 9 and configured to provide a gate scanning signal for the gate line 9. Each shift register is formed by a plurality of second thin film transistors 2, a storage capacitor, and other electrical components. In some examples, the second thin film transistor 2 may be a low temperature polysilicon thin film transistor, and in this case, an active layer 21 of the second thin film transistor 2 may be located in the first light-shielding layer 20. In other words, the active layer 21 of the second thin film transistor 2 and the light-shielding parts in the first light-shielding layer 20 may formed in one process, which will not involve any additional process step or increase the film thickness of the display substrate. In this case, the first light-shielding layer 20 is made of p-Si.

Further, the second thin film transistor 2 may be a top gate thin film transistor or a bottom gate thin film transistor. In the embodiments of the present disclosure, only the case where the second thin film transistor 2 is a top gate thin film transistor is taken as an example for illustration. A source 23 and a drain of the second thin film transistor 2 are disposed in the same layer as the data line 3, a gate 22 of the second thin film transistor 2 is located on a side of the first interlayer insulation layer 103 close to the base substrate 10, and a second gate insulation layer 102 is disposed between the gate 22 and an active layer of the second thin film transistor 2. The source 23 of the second thin film transistor 2 is connected to a source contact region in the active layer 21 of the second thin film transistor 2 through a third connection via running through the second gate insulation layer 102, the first interlayer insulation layer 103, the second gate insulation layer 102, and the second interlayer insulation layer 105. The drain 24 of the second thin film transistor 2 is connected to a drain contact region in the active layer 21 of the second thin film transistor 2 through a fourth connection via running through the second gate insulation layer 102, the first interlayer insulation layer 103, the second gate insulation layer 102, and the second interlayer insulation layer 105. Apparently, a buffer layer 101 may be further provided on a side of the first light-shielding layer 20 close to the base substrate 10.

Further, where the first light-shielding layer 20 does not include the third light-shielding part 203/fourth light-shielding part 204, the second light-shielding layer 200 may be formed simultaneously with the gate 22 of the second thin film transistor 2, so as to shield at least the channel region in the active layer 11 of the first thin film transistor 1. In this case, forming the second light-shielding layer 200 simultaneously with the gate 22 of the second thin film transistor 2 will not involve any additional process step or increase the film thickness of the display substrate.

In some examples, with continued reference to FIG. 2, in addition to the above structures, the display substrate in the embodiments of the present disclosure further includes a third light-shielding layer 7 on a side of the common electrode 5 close to the pixel electrode 4, and an orthographic projection of the third light-shielding layer 7 on the base substrate 10 covers the orthographic projection of the data line 3 on the base substrate 10, so that color crosstalk between adjacent pixels is prevented.

In some examples, with continued reference to FIG. 2, in the embodiments of the present disclosure, the second connection via 82 includes a first sub-via 821 and a second sub-via 822 sequentially arranged in a direction away from the base substrate 10. A transfer electrode 6 is disposed between the first passivation layer 106 and the planarization layer 107, the first sub-via 821 runs through the first gate insulation layer 104, the second interlayer insulation layer 105, and the first passivation layer 106, and the second sub-via 822 runs through the planarization layer 107. The drain of the first thin film transistor 1 is connected to the transfer electrode 6 through the first sub-via 821, and a connection electrode is connected to the pixel electrode 4 through the second sub-via 822.

Further, with continued reference to FIG. 3, in the embodiment of the present disclosure, the active layer of the first thin film transistor 1 includes a first semiconductor section 111 and a second semiconductor section 112. The first semiconductor section 111 and the second semiconductor section 112 each have a first end and a second end. The second end of the first semiconductor section 111 is connected to the first end of the second semiconductor section 112. The first end of the first semiconductor section 111 serves as the source of the first thin film transistor 1, while the second end of the second semiconductor section 112 serves as the drain of the first thin film transistor 1. An extending direction of the second semiconductor section 112 is intersected with an extending direction of the gate line 9, while the first end and the second end of the second semiconductor section 112 are located on two sides of the gate line 9, respectively. With such arrangement, the PPI of the display substrate can be improved.

Although the above takes the case where the first thin film transistor 1 is an oxide thin film transistor as an example for illustration, the first thin film transistor 1 in the embodiments of the present disclosure may be a polysilicon thin film transistor, and in this case, the first light-shielding layer 20 may be made of a-Si (amorphous Silicon).

To make the structure of the display substrate in the embodiments of the present disclosure clearer, several examples of the structure of the display substrate are given below. The display substrate includes pixels in a display region and a shift register of a gate driver circuit in a peripheral region.

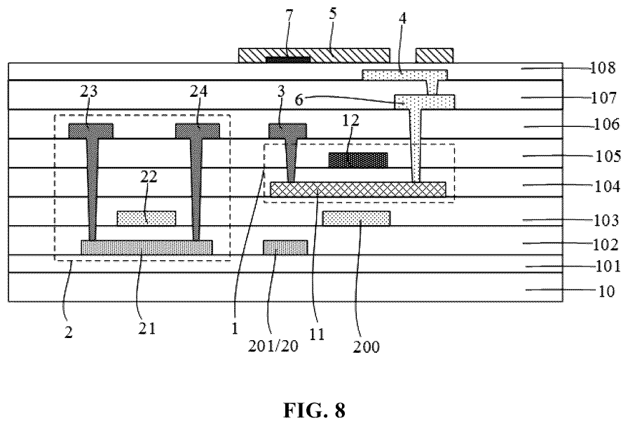

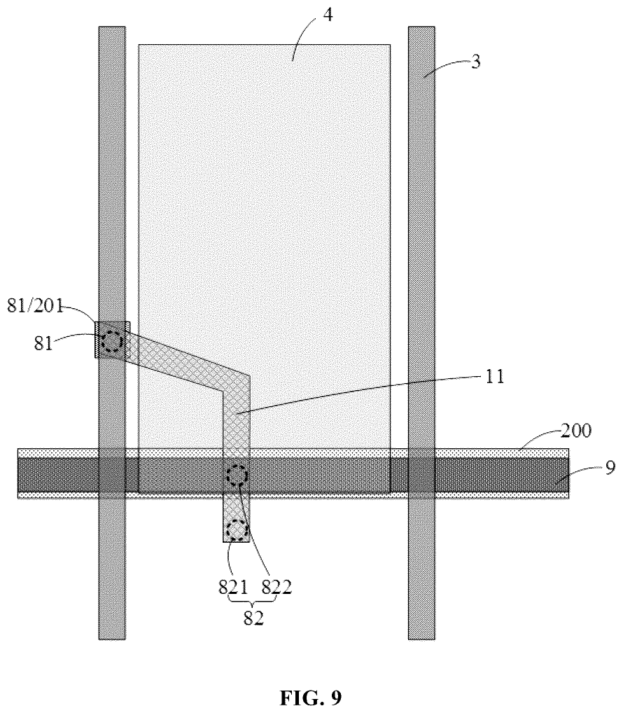

First example: FIG. 8 is a cross-sectional view of a display substrate in a first example according to an embodiment of the present disclosure; and FIG. 9 is a top view of the display substrate in the first example according to an embodiment of the present disclosure. Referring to FIGS. 8 and 9, in the display substrate in this example, the first light-shielding layer 20 includes only a first light-shielding part 201 configured to shield the first connection via 81, and the first light-shielding part 201 is disposed in the same layer as the active layer 21 of the second thin film transistor 2. The channel region of the first thin film transistor 1 is shielded by the second light-shielding layer 200 disposed in the same layer as the gate 22 of the second thin film transistor 2.

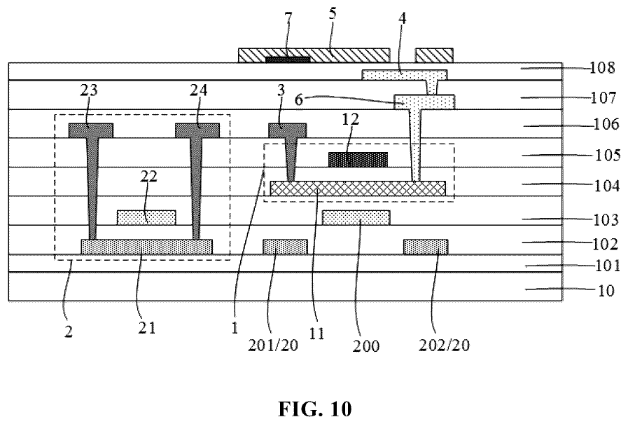

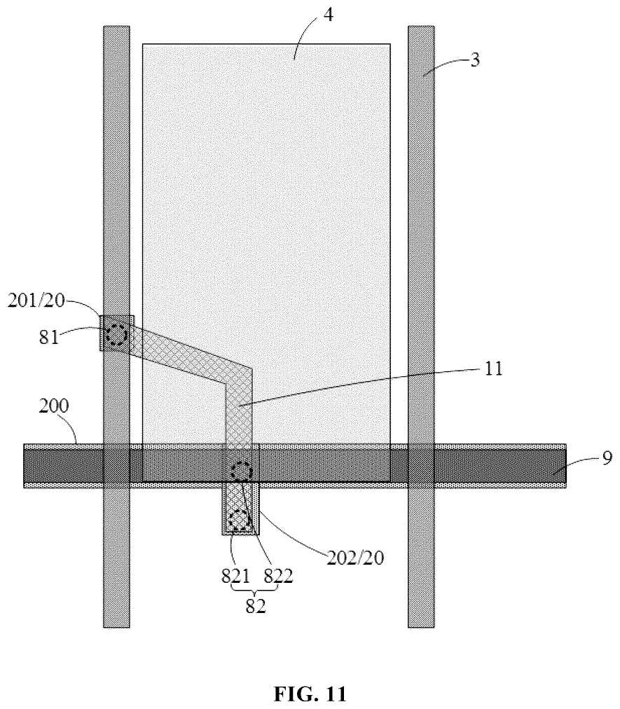

Second example: FIG. 10 is a cross-sectional view of a display substrate in a second example according to an embodiment of the present disclosure; and FIG. 11 is a top view of the display substrate in the second example according to an embodiment of the present disclosure. Referring to FIGS. 10 and 11, in the display substrate in this example, the first light-shielding layer 20 includes a first light-shielding part 201 configured to shield the first connection via 81, and a second light-shielding part 202 configured to shield the second connection via 82, and the first light-shielding part 201 and the second light-shielding part 202 are both disposed in the same layer as the active layer 21 of the second thin film transistor 2. The channel region of the first thin film transistor 1 is shielded by the second light-shielding layer 200 disposed in the same layer as the gate 22 of the second thin film transistor 2.

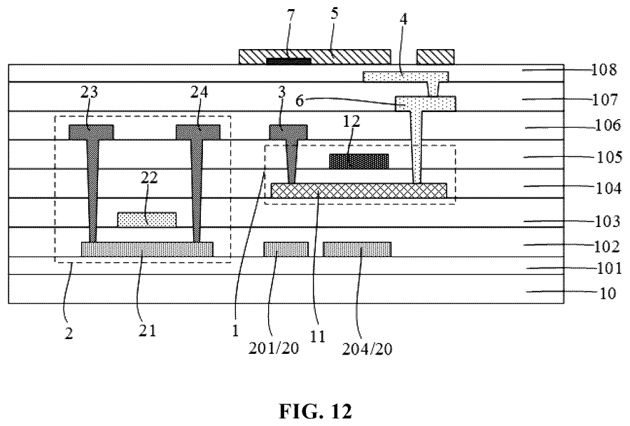

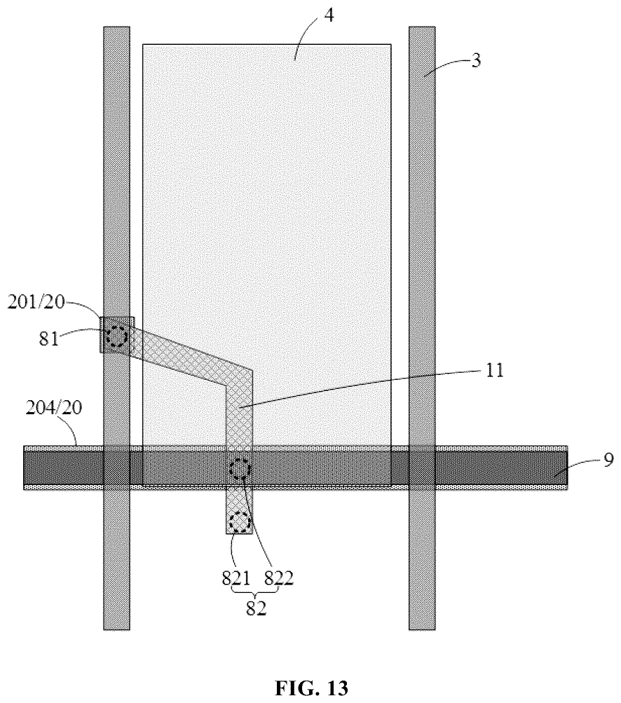

Third example: FIG. 12 is a cross-sectional view of a display substrate in a third example according to an embodiment of the present disclosure; and FIG. 13 is a top view of the display substrate in the third example according to an embodiment of the present disclosure. Referring to FIGS. 12 and 13, in the display substrate in this example, the first light-shielding layer 20 includes a first light-shielding part 201 configured to shield the first connection via 81, and a fourth light-shielding part 204 configured to shield the channel region in the active layer 11 of the first thin film transistor 1 and the gate line 9, and the first light-shielding part 201 and the fourth light-shielding part 204 are both disposed in the same layer as the active layer 21 of the second thin film transistor 2.

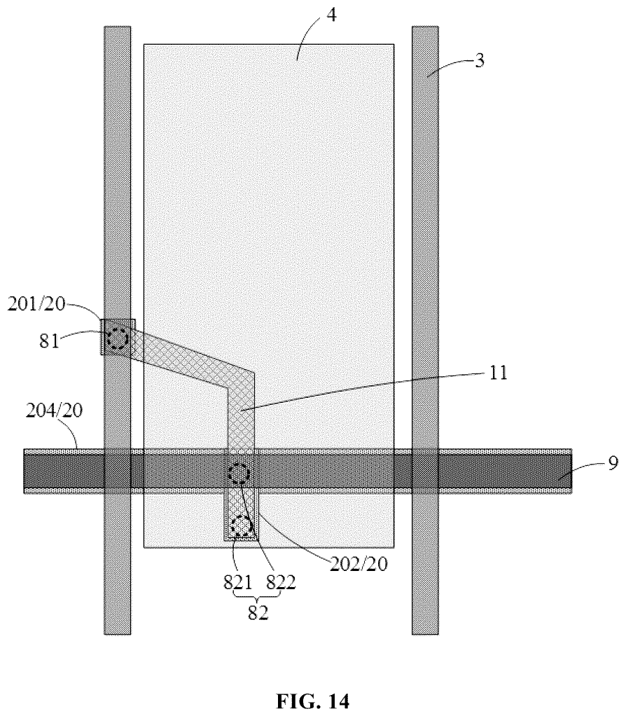

Fourth example: FIG. 14 is a top view of a display substrate in a fourth example according to an embodiment of the present disclosure. A cross-sectional view of the display substrate in the fourth example may refer to FIG. 2. Referring to FIGS. 2 and 13, in the display substrate in this example, the first light-shielding layer 20 includes a first light-shielding part 201 configured to shield the first connection via 81, a second light-shielding part 202 configured to shield the second connection via 82, and a third light-shielding part 203 configured to shield the channel region in the active layer 11 of the first thin film transistor 1, and the first light-shielding part 201, the second light-shielding part 202, and the third light-shielding part 203 are all disposed in the same layer as the active layer 21 of the second thin film transistor 2.

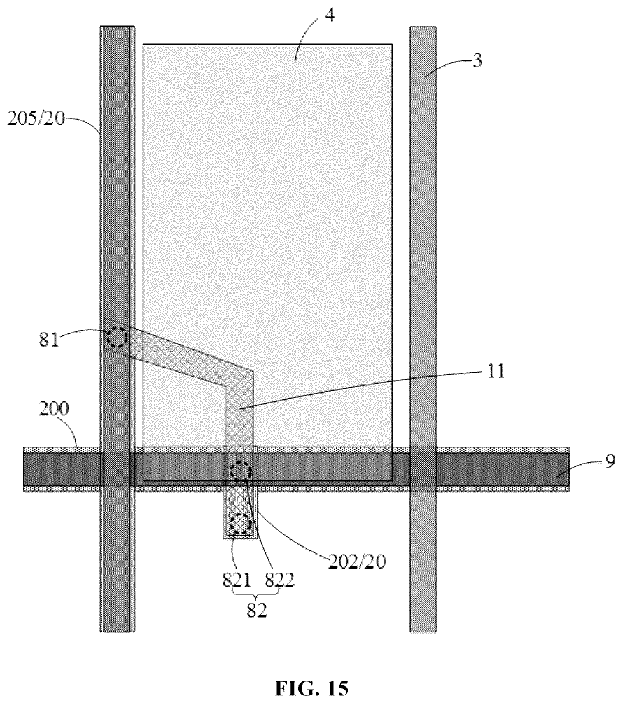

Fifth example: FIG. 15 is a top view of a display substrate in a fifth example according to an embodiment of the present disclosure. A cross-sectional view of the display substrate in the fifth example may refer to FIG. 8. Referring to FIGS. 8, 15 and 7, in this example, the first light-shielding layer 20 includes a fifth light-shielding part 205 and a second light-shielding part 202. The fifth light-shielding part 205 is configured to shield the data line 3 while also shielding the first connection via 81, and the second light-shielding part 202 is configured to shield the second connection via 82.

The first light-shielding layer 20 further includes a fifth light-shielding part 205 configured to shield the data line 3.

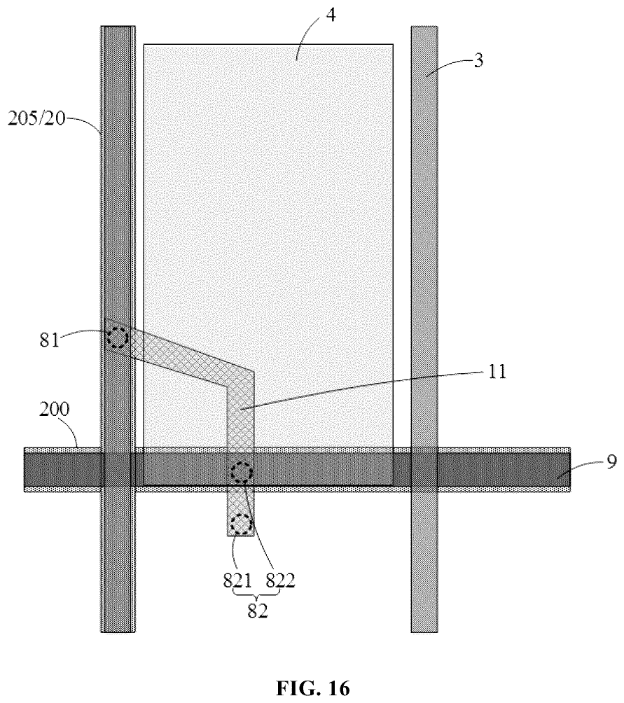

Sixth example: FIG. 16 is a top view of a display substrate in a sixth example according to an embodiment of the present disclosure. A cross-sectional view of the display substrate in the sixth example may refer to FIG. 12. Referring to FIGS. 12 and 16, in this example, the first light-shielding layer 20 includes a fourth light-shielding part 204 and a fifth light-shielding part 205. The fourth light-shielding part 204 shields the gate line 9 and the channel region in the active layer 11 of the first thin film transistor 1, and the fifth light-shielding part shields the data line 3 and the first connection via 81.

It should be noted that only a few exemplary configurations have been given above, and any variations on the above structures are within the scope of the embodiments of the present disclosure.

In a second aspect, an embodiment of the present disclosure provides a method for manufacturing a display substrate, which may be applied to manufacture any of the display substrates described above. The manufacturing method includes providing a base substrate 10, and forming a plurality of gate lines 9, a plurality of data lines 3 and a plurality of pixels on the base substrate 10. Each pixel is formed by forming a first thin film transistor 1, a first display electrode, and a second display electrode on the base substrate 10. The first thin film transistor 1 has a gate 12 connected to a gate line 9, a source connected to a data line 3 through a first connection via 81, and a drain connected to the first display electrode through a second connection via 82. The method further includes: forming a first light-shielding layer 20 on a side of the first thin film transistor 1 close to the base substrate 10. The first light-shielding layer 20 is made of a silicon-containing semiconductor material. The light-shielding layer includes a first light-shielding part 201 and/or a second light-shielding part 202. Where the first light-shielding layer 20 includes the first light-shielding part 201, an orthographic projection of the first light-shielding part 201 on the base substrate 10 covers the orthographic projection of the first connection via 81 on the base substrate 10. Where the first light-shielding layer 20 includes the second light-shielding part 202, an orthographic projection of the second light-shielding part 202 on the base substrate 10 covers the orthographic projection of the second connection via 82 on the base substrate 10.

In the embodiment of the present disclosure, a silicon-containing semiconductor material is selected to form the first light-shielding layer 20 to shield the first connection via 81 and/or the second connection via 82, so that by means of the optical characteristics of the silicon-containing semiconductor material, therefore, light leakage at positions of the connection vias can be reduced without affecting the aperture ratio.

In some examples, an active layer 11 of the first thin film transistor 1 is closer to the base substrate 10 than the gate. In other words, the first thin film transistor 1 is a top gate thin film transistor. The first light-shielding layer 20 further includes a third light-shielding part 203, and an orthographic projection of the third light-shielding part 203 on the base substrate 10 covers an orthographic projection of a channel region in the active layer on the base substrate 10.

In some examples, the first light-shielding layer 20 further includes a plurality of fourth light-shielding parts 204 and/or a plurality of fifth light-shielding parts 205. Where the first light-shielding layer 20 includes the fourth light-shielding parts 204, an orthographic projection of one fourth light-shielding part 204 on the base substrate 10 covers an orthographic projection of one gate line 9 on the base substrate 10. Where the first light-shielding layer 20 includes the fifth light-shielding parts 205, an orthographic projection of one fifth light-shielding part 205 on the base substrate 10 covers an orthographic projection of one data line 3 on the base substrate 10. The fourth light-shielding part 204 and the fifth light-shielding part 205 are provided to shield the gate line 9 and the data line 3, respectively, because the gate line 9 and the data line 3 are not linear structures and are made of a metal material, which may cause light deflection and thus light leakage when light passes through edges of the metal signal lines, and in this case, light leakage can be effectively reduced by shielding the gate line 9 and the data line 3 by the fourth light-shielding part 204 and the fifth light-shielding part 205, respectively.

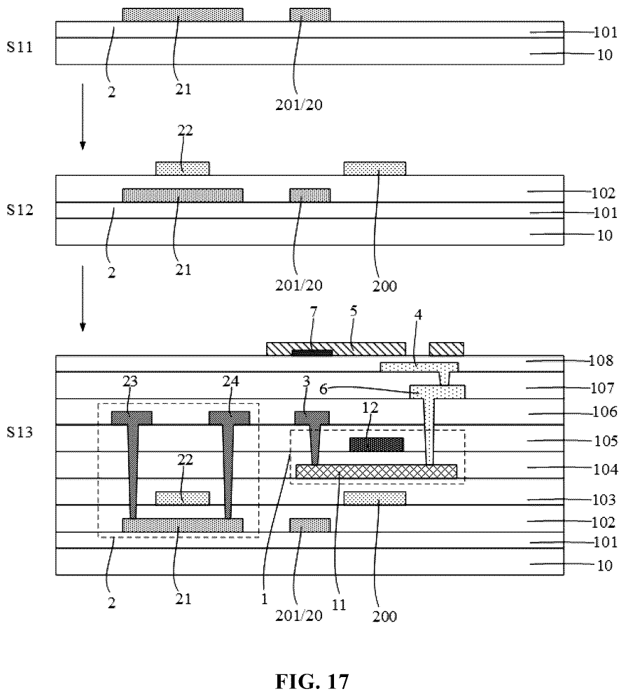

To make the method for manufacturing a display substrate according to the embodiment of the present disclosure clearer, the following description is made in conjunction with the method for manufacturing a display substrate in the first example. FIG. 17 is a flowchart of a method for manufacturing a display substrate according to an embodiment of the present disclosure. As shown in FIG. 17, the method specifically includes the following steps S11 to S13.

At S11, providing a base substrate 10, and sequentially forming a buffer layer 101 and a first light-shielding layer 20 on the base substrate 10. The first light-shielding layer 20 includes a first light-shielding part 201, and an active layer 21 of a second thin film transistor 2.

In some examples, the base substrate 10 is selected to be glass-based, and the step S11 further includes a step of cleaning the base substrate 10.

In some examples, the buffer layer 101 may be formed through a chemical vapor deposition (CVD) process, and made of a material including one or more of silicon nitride, silicon oxide, or silicon oxynitride. The buffer layer 101 has a thickness between 1000 Å and 6000 Å. In some examples, the first light-shielding layer 20 may be formed by: forming an a-Si layer having a thickness between 200 Å and 2000 Å through a CVD process; then forming p-Si through crystallization; and finally forming the first light-shielding layer 20 through a patterning process.

At S12, forming a second gate insulation layer 102, and forming a gate 22 of the second thin film transistor 2 and a second light-shielding layer 200 on a side of the second gate insulation layer 102 away from the base substrate 10.

In some examples, the second gate insulation layer 102 may be formed by a CVD or atomic layer deposition (ALD) process. The second gate insulation layer 102 may be formed by a material including one or more of silicon nitride, silicon oxide, or silicon oxynitride, and have a thickness between 600 Å and 2000 Å.

In some examples, a first conductive film layer may be formed by sputtering, thermal evaporation, plasma enhanced chemical vapor deposition, low pressure chemical vapor deposition, atmospheric pressure chemical vapor deposition, or electron cyclotron resonance chemical vapor deposition, and then a pattern including the gate 22 of the second thin film transistor 2 and the second light-shielding layer 200 may be formed through a patterning process. The first conductive film layer may be a MoNb/Cu laminated layer, or an MTD/Cu laminated layer, or a MoNb/Cu/MTD laminated layer, and have a thickness between 200 nm and 1200 nm.

At S13, forming a first interlayer insulation layer 103, and sequentially forming an active layer 11 of the first thin film transistor 1, a first gate insulation layer 104, a gate 12 of the first thin film transistor 1, a second interlayer insulation layer 105, a source 23 and a drain of the second thin film transistor 2 and a data line 3 disposed in the same layer, a first passivation layer 106, a transfer electrode 6, a planarization layer 107, a pixel electrode 4, an interlayer insulation layer (a second passivation layer 108) , a third light-shielding layer 7 and a common electrode 5 on a side of the first interlayer insulation layer 103 away from the base substrate 10.

The data line 3 is connected to a source contact region (i.e., source) in the active layer 11 of the first thin film transistor 1 through a first connection via 81 running through the second interlayer insulation layer 105 and the first gate insulation layer 104. The second connection via 82 includes a first sub-via 821 and a second sub-via 822 sequentially arranged in a direction away from the base substrate 10. A transfer electrode 6 is disposed between the first passivation layer 106 and the planarization layer 107, the first sub-via 821 runs through the first gate insulation layer 104, the second interlayer insulation layer 105, and the first passivation layer 106, and the second sub-via 822 runs through the planarization layer 107. The drain of the first thin film transistor 1 is connected to the transfer electrode 6 through the first sub-via 821, and a connection electrode is connected to the pixel electrode 4 through the second sub-via 822. The source 23 of the second thin film transistor 2 is connected to a source contact region in the active layer 21 of the second thin film transistor 2 through a third connection via running through the second gate insulation layer 102, the first interlayer insulation layer 103, the second gate insulation layer 102, and the second interlayer insulation layer 105. The drain 24 of the second thin film transistor 2 is connected to a drain contact region in the active layer 21 of the second thin film transistor 2 through a fourth connection via running through the second gate insulation layer 102, the first interlayer insulation layer 103, the second gate insulation layer 102, and the second interlayer insulation layer 105.

In a third aspect, an embodiment of the present disclosure provides a display apparatus, including the display substrate as described above.

The display apparatus may be a liquid crystal display apparatus or an electroluminescent display apparatus, such as a liquid crystal panel, electronic paper, an OLED panel, a mobile phone, a tablet, a television, a monitor, a notebook computer, a digital album, a navigator or any other product or component having a display function. The display apparatus of this embodiment has better display quality.

It will be appreciated that the above implementations are merely exemplary implementations for the purpose of illustrating the principle of the present disclosure, and the present disclosure is not limited thereto. Various modifications and improvements can be made by those skilled in the art without departing from the spirit and essence of the present disclosure. Accordingly, all of the modifications and improvements also fall into the protection scope of the present disclosure.

1. A display substrate, comprising a base substrate, and a plurality of gate lines, a plurality of data lines, and a plurality of pixels on the base substrate; wherein each pixel comprises a first thin film transistor, a first display electrode, and a second display electrode; wherein the first thin film transistor has a gate connected to a gate line, a source connected to a data line through a first connection via, and a drain connected to the first display electrode through a second connection via; and wherein the display substrate further comprises a first light-shielding layer on a side of the first thin film transistor close to the base substrate; the first light-shielding layer is made of a silicon-containing semiconductor material; and an orthographic projection of the first light-shielding layer on the base substrate covers at least an orthographic projection of one of the first connection via or the second connection via on the base substrate.

2. The display substrate according to claim 1, wherein the first light-shielding layer comprises a first light-shielding part and/or a second light-shielding part;
in a case where the first light-shielding layer comprises the first light-shielding part, an orthographic projection of the first light-shielding part on the base substrate covers the orthographic projection of the first connection via on the base substrate; and
in a case where the first light-shielding layer comprises the second light-shielding part, an orthographic projection of the second light-shielding part on the base substrate covers the orthographic projection of the second connection via on the base substrate.

3. The display substrate according to claim 2, wherein an active layer of the first thin film transistor is made of a metal oxide semiconductor material, and is closer to the base substrate than the gate; and the first light-shielding layer further comprises a third light-shielding part, and an orthographic projection of the third light-shielding part on the base substrate covers an orthographic projection of a channel region in the active layer on the base substrate.

4. The display substrate according to claim 3, wherein for the third light-shielding part and the channel region having overlapped orthographic projections on the base substrate, a minimum distance between contours of the orthographic projections of the third light-shielding part and the channel region on the base substrate is between 0.5 μm and 5 μm.

5. The display substrate according to claim 1, wherein the first light-shielding layer further comprises a plurality of fourth light-shielding parts and/or a plurality of fifth light-shielding parts;
in a case where the first light-shielding layer comprises the fourth light-shielding parts, an orthographic projection of one fourth light-shielding part on the base substrate covers an orthographic projection of one gate line on the base substrate; and
in a case where the first light-shielding layer comprises the fifth light-shielding parts, an orthographic projection of one fifth light-shielding part on the base substrate covers an orthographic projection of one data line on the base substrate.

6. The display substrate according to claim 5 wherein for the fourth light-shielding part and the gate line having overlapped orthographic projections on the base substrate, a minimum distance between contours of the orthographic projections of the fourth light-shielding part and the gate line on the base substrate is between 0.5 μm and 5 μm.

7. The display substrate according to claim 5, wherein for the fifth light-shielding part and the data line having overlapped orthographic projections on the base substrate, a minimum distance between contours of the orthographic projections of the fifth light-shielding part and the data line on the base substrate is between 0.5 μm and 5 μm.

8. The display substrate according to claim 1, wherein the display substrate comprises a display region and a peripheral region around the display region, and the peripheral region comprises a gate driver circuit on the base substrate; each shift register of the gate driver circuit comprises a second thin film transistor; and an active layer of the second thin film transistor is disposed in the same layer as the first light-shielding layer.

9. The display substrate according to claim 1, wherein the display substrate comprises a display region and a peripheral region around the display region, and the peripheral region comprises a gate driver circuit and a second light-shielding layer on the base substrate; an orthographic projection of the second light-shielding layer on the base substrate covers an orthographic projection of a channel region in an active layer of the first thin film transistor on the base substrate;
each shift register of the gate driver circuit comprises a second thin film transistor; and a gate of the second thin film transistor is disposed in the same layer as the second light-shielding layer.

10. The display substrate according to claim 1, wherein the second connection via comprises a first sub-via and a second sub-via sequentially arranged in a direction away from the base substrate; and the drain of the first thin film transistor is connected to a transfer electrode through the first sub-via, and the transfer electrode is connected to the first display electrode through the second sub-via.

11. The display substrate according to claim 1, wherein an active layer of the first thin film transistor comprises a first semiconductor section and a second semiconductor section; the first semiconductor section and the second semiconductor section each have a first end and a second end; the second end of the first semiconductor section is connected to the first end of the second semiconductor section; the first end of the first semiconductor section serves as the source of the first thin film transistor, and the second end of the second semiconductor section serves as the drain of the first thin film transistor; and
an extending direction of the second semiconductor section is intersected with an extending direction of the gate line, and along an extending direction of the data line, the first end and the second end of the second semiconductor section are on two sides of the gate line, respectively.

12. The display substrate according to claim 2, wherein the first light-shielding layer comprises the first light-shielding part, for the first light-shielding part and the first connection via having overlapped orthographic projections on the base substrate, a minimum distance between contours of the orthographic projections of the first light-shielding part and the first connection via on the base substrate is between 0.5 μm and 5 μm, or
wherein the first light-shielding layer comprises the second light-shielding part, for the second light-shielding part and the second connection via having overlapped orthographic projections on the base substrate, a minimum distance between contours of the orthographic projections of the second light-shielding part and the second connection via on the base substrate is between 0.5 μm and 5 μm.

13. (canceled)

14. The display substrate according to claim 2, wherein the first light-shielding layer comprises the first light-shielding part, an orthographic projection of the first light-shielding part on the base substrate has a contour in the shape of any one or more of a square, a rectangle, a parallelogram, a circle, an ellipse, an ellipse-like shape or an irregular shape, or
wherein the first light-shielding layer comprises the second light-shielding part, an orthographic projection of the second light-shielding part on the base substrate has a contour in the shape of any one or more of a square, a rectangle, a parallelogram, a circle, an ellipse, an ellipse-like shape or an irregular shape.

15. (canceled)

16. The display substrate according to claim 1, wherein an interlayer insulation layer is provided between the first display electrode and the second display electrode, and a third light-shielding layer is provided on a side of the second display electrode close to the interlayer insulation layer; and an orthographic projection of the third light-shielding layer on the base substrate covers an orthographic projection of the data line on the base substrate.

17. The display substrate according to claim 1, wherein an active layer of the first thin film transistor is made of a metal oxide semiconductor material, and the first light-shielding layer is made of a material comprising polysilicon; or, the active layer of the first thin film transistor is made of a polysilicon material, and the first light-shielding layer is made of a material comprising amorphous silicon.

18. A method for manufacturing a display substrate, comprising:
providing a base substrate, and forming a plurality of gate lines, a plurality of data lines and a plurality of pixels on the base substrate; wherein each pixel is formed by forming a first thin film transistor, a first display electrode, and a second display electrode on the base substrate; wherein the first thin film transistor has a gate connected to a gate line, a source connected to a data line through a first connection via, and a drain connected to the first display electrode through a second connection via; and wherein the method further comprises:
forming a first light-shielding layer on a side of the first thin film transistor close to the base substrate; wherein the first light-shielding layer is made of a silicon-containing semiconductor material; and an orthographic projection of the first light-shielding layer on the base substrate covers at least an orthographic projection of one of the first connection via or the second connection via on the base substrate.

19. The method according to claim 18, wherein the first light-shielding layer comprises a first light-shielding part and/or a second light-shielding part;
in a case where the first light-shielding layer comprises the first light-shielding part, an orthographic projection of the first light-shielding part on the base substrate covers the orthographic projection of the first connection via on the base substrate; and
in a case where the first light-shielding layer comprises the second light-shielding part, an orthographic projection of the second light-shielding part on the base substrate covers the orthographic projection of the second connection via on the base substrate.

20. The method according to claim 18, wherein an active layer of the first thin film transistor is made of a metal oxide semiconductor material, and is closer to the base substrate than the gate; and the first light-shielding layer further comprises a third light-shielding part, and an orthographic projection of the third light-shielding part on the base substrate covers an orthographic projection of a channel region in the active layer on the base substrate.

21. The method according to claim 18, wherein the first light-shielding layer further comprises a plurality of fourth light-shielding parts and/or a plurality of fifth light-shielding parts;
in a case where the first light-shielding layer comprises the fourth light-shielding parts, an orthographic projection of one fourth light-shielding part on the base substrate covers an orthographic projection of one gate line on the base substrate; and
in a case where the first light-shielding layer comprises the fifth light-shielding parts, an orthographic projection of one fifth light-shielding part on the base substrate covers an orthographic projection of one data line on the base substrate.

22. The methods according to claim 18, further comprising forming a gate driver circuit on the base substrate; wherein each shift register of the gate driver circuit comprises a second thin film transistor; and an active layer of the second thin film transistor is disposed in the same layer as the first light-shielding layer.
